(19) United States
(12) Patent Application Publication
(10) Pub. No.: US 2016/0061892 A1
(43) Pub. Date: Mar. 3, 2016

(54) SCAN PROGRAMMABLE REGISTER CONTROLLED CLOCK ARCHITECTURE FOR TESTING ASYNCHRONOUS DOMAINS

(71) Applicant: QUALCOMM Incorporated, San Diego, CA (US)

(72) Inventors: Rajesh Tiwari, Bangalore (IN); Manish Kumar Pillai, Bangalore (IN)

(21) Appl. No.: 14/609,341

(22) Filed: Jan. 29, 2015

Related U.S. Application Data
(60) Provisional application No. 62/043,866, filed on Aug. 29, 2014.

(51) Int. Cl. G01R 31/3177

(52) U.S. Cl. CPC G01R 31/3177

(57) ABSTRACT

Embodiments contained in the disclosure provide a method of testing an electronic chip. The method comprises: scanning a test program into multiple clock registers; pulsing a clock to activate multiple asynchronous clock domain registers one at a time; staggering capture across and within the multiple asynchronous clock domains; shifting acquired data out of the multiple scan chains simultaneously; and then comparing the data scanned out with the test program data.

### CLAIM OF PRIORITY

The present Application for Patent claims priority to Provisional Application No. 62/043,866, entitled “Scan programmable register controlled clock architecture for testing asynchronous domains” filed Aug. 29, 2014, and assigned to the assignee hereof and hereby expressly incorporated by reference herein.

### BACKGROUND INFORMATION

1. Technical Field

The present invention relates generally to an architecture for testing asynchronous domains, in particular, asynchronous clock domains.

2. Background Information

Scan design techniques are frequently used in conjunction with automatic test pattern generation (ATPG) tools to efficiently test chips, including system-on-chip (SoC) devices. A typical scan, such as a boundary scan, uses scan chain or multiple scan chains that may be formed on the SoC or other chip. These chains are formed by connecting flip-flops in the chip as one or more long shift registers when a scan mode is utilized for the chip. During the scan mode, a scan shift operation or scan capture may be performed. The shift operation involves loading one or more test patterns into the scan chains. While the scan shift operation is in progress normal operation of the chip may be suspended. Once the test patterns have been loaded, scan capture may begin. Pseudo-functional operations of the chip may be performed, which are based on functional inputs loaded into the scan chains. Once the scan operation is complete, the results may be shifted out and compared with the pattern expected for the chip, providing verification of correct chip operation.

SoCs frequently use multiple clocks and frequencies, and thus, are multiple clock domains. During the chip's functional operation, the interface across the multi-clock domains are asynchronous, and timing is not critical. This allows clock trees for different clocks to be balanced independently. Timing issues may appear. Clock imbalance across the multi-clock domains may be difficult to resolve and may require the use of lock-up latches.

While multi-clock architecture is often used it remains difficult to test in an efficient and effective manner. Previous testing methods used either additional hardware controls that limited the number of devices that could be tested together or were not readily configurable, and may have been designed for only one configuration. This may limit simulation tool selection. In other cases, hardware will not allow enablement of multiple clock configurations, such as is required for debug, test time optimization as static timing analysis (STA). In addition, one-hot-decoder (OHD) logic may be used as part of a compression solution, which may cause quality of resilience (QoR) issues when higher compression targets are involved. Design for test (DFT) may involve reducing testing time and cost.

There is a need in the art for a scan programmable register controlled clock architecture for testing asynchronous domains that is configurable, uses minimum hardware controls and should be capable of testing multiple clocks and modes overcoming the limitations discussed.

### SUMMARY

Embodiments contained in the disclosure provide a method of testing an electronic chip. The method comprises: scanning a test program into multiple clock registers; pulsing a clock to activate multiple asynchronous clock domain registers one at a time; staggering capture across and within the multiple asynchronous clock domains; shifting acquired data out of the multiple scan chains simultaneously; and then comparing the data scanned out with the test program data.

A further embodiment provides an apparatus for testing an electronic chip. The apparatus comprises: an electronic chip core having at least one embedded core; at least one clock register; at least two asynchronous clock domains; and a programmable clock generator. A memory for storing a test program may also be included.

A still further embodiment provides an apparatus for testing an electronic chip. The apparatus comprises: means for scanning a test program into multiple clock registers; means for pulsing a clock to activate multiple asynchronous clock domain registers one at a time; means for staggering capture across and within the multiple asynchronous clock domains; means for shifting acquired data out of multiple scan chains simultaneously; and means for comparing data scanned out with the test program data.

A yet further embodiment provides a non-transitory computer-readable media including program instructions, which when executed by a processor cause the processor to perform a method comprising the steps of: scanning a test program into multiple clock registers; pulsing a clock to activate multiple asynchronous clock domain registers one at a time; staggering capture across and within the multiple asynchronous clock domains; shifting acquired data out of multiple scan chains simultaneously; and comparing data scanned out with the test program data.

### BRIEF DESCRIPTION OF THE DRAWINGS

FIG. 1 is a block diagram of a scan programmable register controlled clock architecture, according to an embodiment.

FIG. 2 illustrates capture clock waveforms, according to an embodiment.

FIG. 3 provides a block diagram of a scan compression architecture, according to an embodiment.

FIG. 4 depicts handling different clock requirements using the scan programmable register controlled clock architecture, according to an embodiment.

FIG. 5 depicts a further embodiment of handling different clock requirements using the scan programmable register controlled clock architecture, according to an embodiment.

FIG. 6 is a flowchart of a method capturing clock waveforms, according to an embodiment.

FIG. 7 is a flowchart of a method of handling different clock requirements, according to an embodiment.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

As used in this application, the terms “component,” “module,” “system,” and the like are intended to include a computer-related entity, such as, but not limited to hardware, firmware, a combination of hardware and software, or software in execution. For example, a component may be, but is not limited to being, a process running on a processor, a processor, an object, an executable, a thread of execution, a program, and/or a computer. By way of illustration, both an application running on a computing device and the computing device can be a component. One or more components can reside within a process and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

As used herein, the term “determining” encompasses a wide variety of actions and therefore, “determining” can include calculating, computing, processing, deriving, investigating, looking up (e.g., looking up in a table, a database or another data structure), ascertaining and the like. Also, “determining” can include resolving, selecting, choosing, establishing, and the like.

The phrase “based on” des not mean “based only on,” unless expressly specified otherwise. In other words, the phrase “based on” describes both “based only on” and “based at least on.”

Moreover, the term “or” is intended to mean an inclusive “or” rather than an exclusive “or.” That is, unless specified otherwise, or clear from the context, the phrase “X employs A or B” is intended to mean any of the natural permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The various illustrative logical blocks, modules, and circuits described in connection with the present disclosure may be implemented or performed with a general purpose processor, a digital signal processor (DSP), an application specific integrated circuit (ASIC), a field programmable gate array (FPGA), or other programmable logic device, discrete gate or transistor logic, discrete hardware components or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of DSP and a microprocessor, a plurality of microprocessors, one or more microprocessors in conjunction with a DSP core or any other such configuration.

The steps of a method or algorithm described in connection with the present disclosure may be embodied directly in hardware, in a software module executed by a processor or in a combination of the two. A software module may reside in any form of storage medium that is known in the art. Some examples of storage media that may be used include RAM memory, flash memory, ROM memory, EPROM memory, EEPROM memory, registers, a hard disk, a removable disk, a CD-ROM, and so forth. A software module may comprise a single instruction, or many instructions, and may be distributed over several different code segments, among different programs and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the desired method. The method steps and/or actions my be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in software, the functions may be stored as one or more instructions on a computer-readable medium. A computer-readable medium may be any available medium that can be accessed by a computer. By way of example, and not limitation, a computer-readable medium may comprise RAM, ROM, EEPROM, CD-ROM or other optical disk storage, magnetic disk storage, or other magnetic storage devices, or any other medium that can be used to carry or store desired program code in the form of instructions or data structure and that can be accessed by a computer. Disk and disc, as used herein, includes compact disk (CD), laser disk, optical disk, digital versatile disk (DVD), floppy disk, and Blu-ray® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

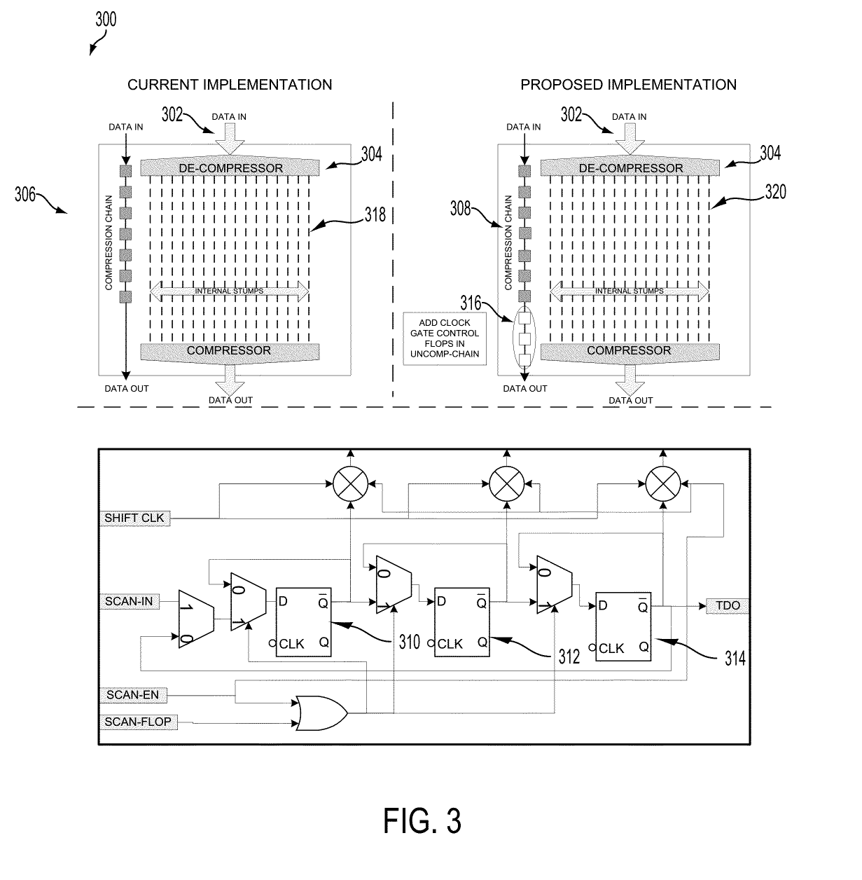

Further, it should be appreciated that modules and/or other appropriate means for performing the methods and techniques described herein, such as those illustrated by FIGS. 3-5, can be downloaded and/or otherwise obtained by a mobile device and/or base station as applicable. For example, such a device can be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a mobile device and/or base station can obtain the various methods upon coupling or providing the storage means to the device. Moreover, any other suitable technique for providing the methods and techniques described herein to a device can be utilized.

A clocking structure on a chip may include multiple clock domains. In normal operation of the chip, each domain is clocked by its own clock via their respective multiplexers. Each of the multiple clocks is asynchronous to each other. The clock trees of the multiple clock domains need not be balanced. During scan capture of the chip the multiple clock domains are clocked by a single scan clock. The scan clock generates an input scan clock signal when the chip is in the scan mode. Synchronous scan clock signals are fed to the multiple clock domains.

During a scan shift operation where a scan enable signal is set high, test patterns may be loaded to scan chains in the multiple clock domains. Next, during a scan capture operation, where the scan enable signal is set low, a pseudo-functional operation of the chip may be performed, based on the functional inputs to the chip as well as the test patterns loaded to the scan chains. The scan capture operation does not merely move test patterns across flip-flops in the chip, rather the scan capture may involve applying functional inputs as well to various combinational circuits in the clock domains. As a result, the synchronous interfaces based on the single scan clock may require the clock trees of the multiple clock domains to be balanced and may also require timing closure on all clock paths.

Embodiments disclosed herein provide a scan programmed register controlled clock architecture. The embodiments provide a single clock pin for testing multiple asynchronous clock domains. In addition, embodiments support staggered capture across or within the multiple clock domains. This is achieved with no additional static timing analysis (STA) closure overhead. Further embodiments provides a scan compression architecture that incorporates a control register scan chain to overcome difficulties with controllability and aliasing issues, as well a compression issues. A still further embodiment provides for programmable one-hot decoder function to support different asynchronous clock requirements, all of which may reside on the same SoC.

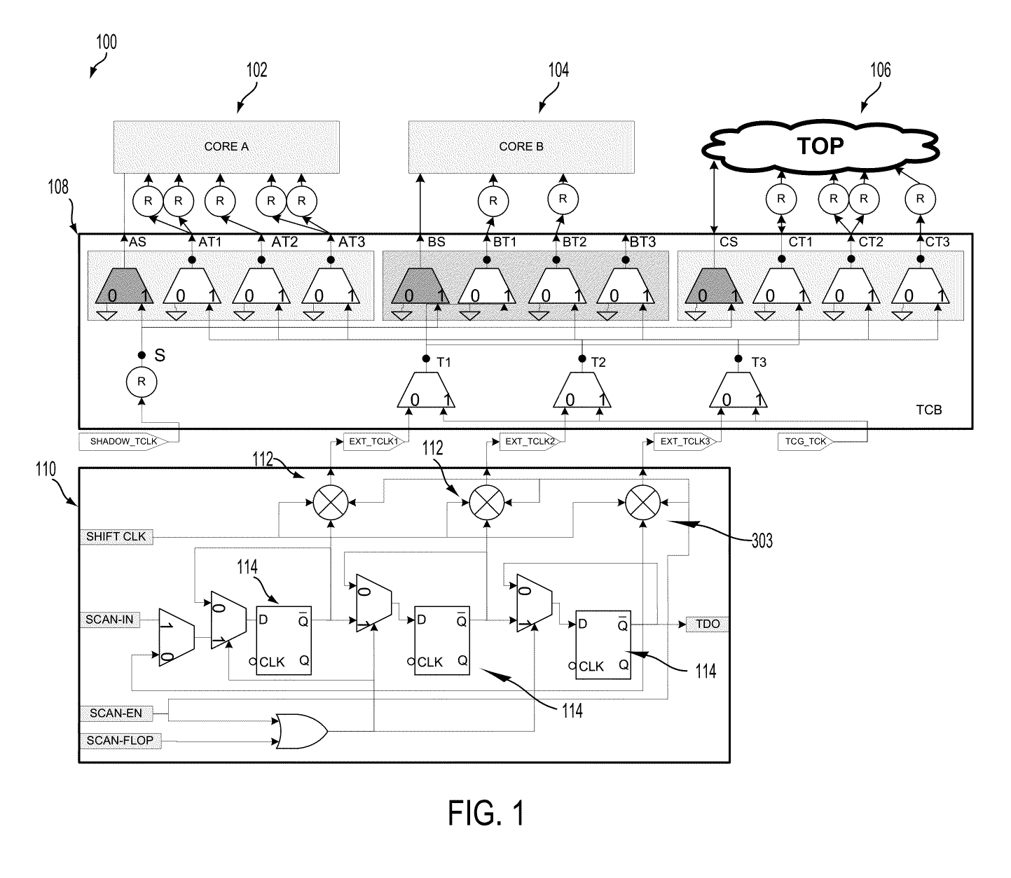

FIG. 1 illustrates a scan programmable register controlled architecture 100 for testing asynchronous domains, according to an embodiment. Although three clock domains are illustrated (labeled as Core A 102, Core B 104, and Core C 106), the architecture is not limited to three clock domains and may be extended. FIG. 1 includes the system and logic circuitry as well as the multiple clock domains. The system includes a shift register 110, a scan programmable n-bit decoder 114, integrated clock gating cells 112, and multiplexers 108 for each clock domain.

The scna programmable n-bit clock decoder is connected to the tester. Integrated clock gating cells (ICGs) are connected to the programmable n-bit clock decoder and to the tester. Scan enable nodes and clock input nodes are also connected to the test. Function enable nodes are connected to the corresponding output nodes of the programmable n-bit clock decoder. Each of the multiplexers is connected to a respective ICG. The multiplexers are coupled to clock output nodes of the ICG and are also connect to the individual multiple clocks. Each of the multiple clocks is dedicated to one of the multiple clock domains.

Normally, the multi-clock domains are clocked by the individual clocks via their respective multiplexers with the individual clocks asynchronous to each other. In the scan capture mode of operation of the SoC, the shift register, which may be a part of the scan chains, processes select data in response to scan capture pulses. In contrast to other methods, the architecture described herein permits selection of multiple clock domains at the same time for performing the scan capture operation. The decoder then generates a code which may have one enable bit. This code may be forwarded to the enable nodes of the ICGs as function enable signals. At the same time, the tester applies a logical low signal to the nodes and the scan capture pulse to the clock input nodes. This is done for each clock domain to be tested.

In response, the respective multiplexers associated with the multiple clock domains, forward the scan capture pulse to the respective clock domains to perform the scan capture operation. Any one input allows a clock to operate.

The logic table provided in FIG. 1 provides that when the scan enable logic is set to 1 and the scan flop logic is not set, then the shift path is enabled. If the scan enable logic is set to 0 and the scan flop logic is also set to 0, then the flops will hold the shifted value. This allows for a single clock domain with a staggered capture as a scan option. If the scan enable logic is set to 0 and the scan flop logic is set to 1, then the flops will capture the shifted value, and multiple clock domain staggered capture is possible. The logic provided allows the multiplexers to pass a scan capture pulse from the ICG to the multiple clock domains.

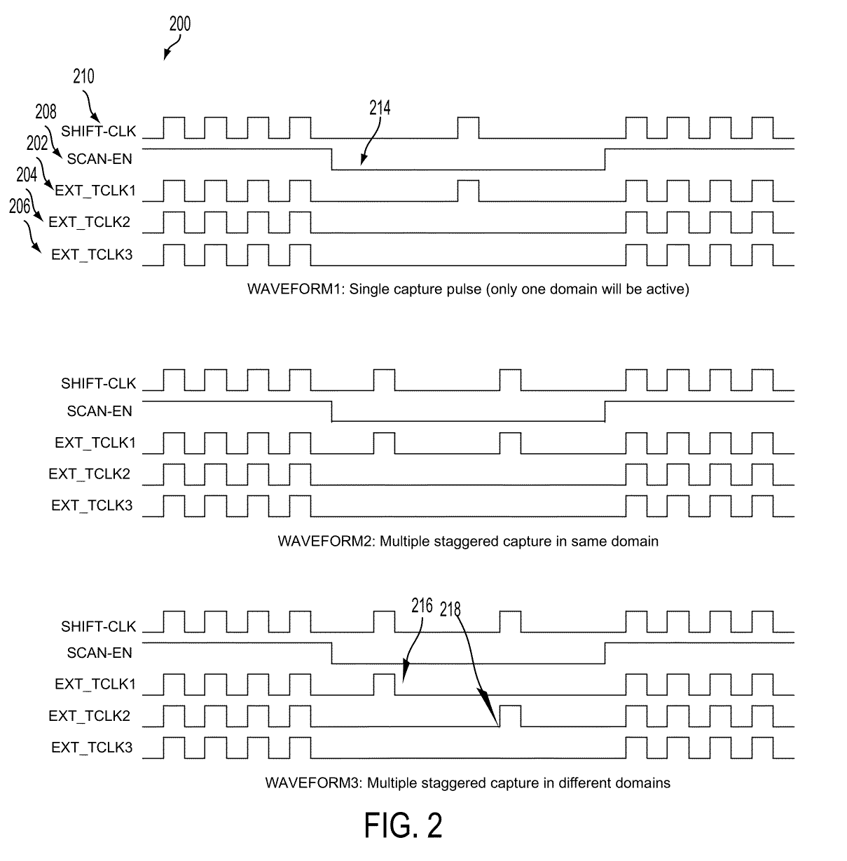

FIG. 2 illustrates the timing diagrams of the scan programmable register controlled clock architecture. In particular, FIG. 2 depicts a basic scan capture operation for three clock domains 202, 204, and 206. A scan shift operation is performed when a scan enable signal 208 is set to logic 1 212, active. During the scan shift operation, a scan shift pulse is fed to the multiple clock domains. When the scan enable signal 208 is set to logic 0 214, inactive, a scan capture may be initiated with a clock domain. Multiple clock domains may be set active at various times 216 and 218, to enable multiple clock domain testing.

FIG. 3 depicts the system architecture 300 for the scan compression architecture. In addition, FIG. 3 illustrates that since the constrained flops are part of the uncompressed chain, issues related to aliasing and controllability, and pattern inflation are prevented. FIG. 3 also illustrates the data 302 entering the design, decompression 304, and initialization of the multiple channels. The clock gate control flops 310, 312, and 314, are also shown. Each clock is shifted in, with the data being shifted in 306 and 308, dependent on the length of the flip-flop chain. The additional scan flop 316 enables staggered capture across multiple clock domains. Since the constrained flops are part of the uncompressed chain 318, 320, aliasing/controllability, and pattern inflation issues are prevented. The uncompressed chain forms a part of the ATPG for top level runs.

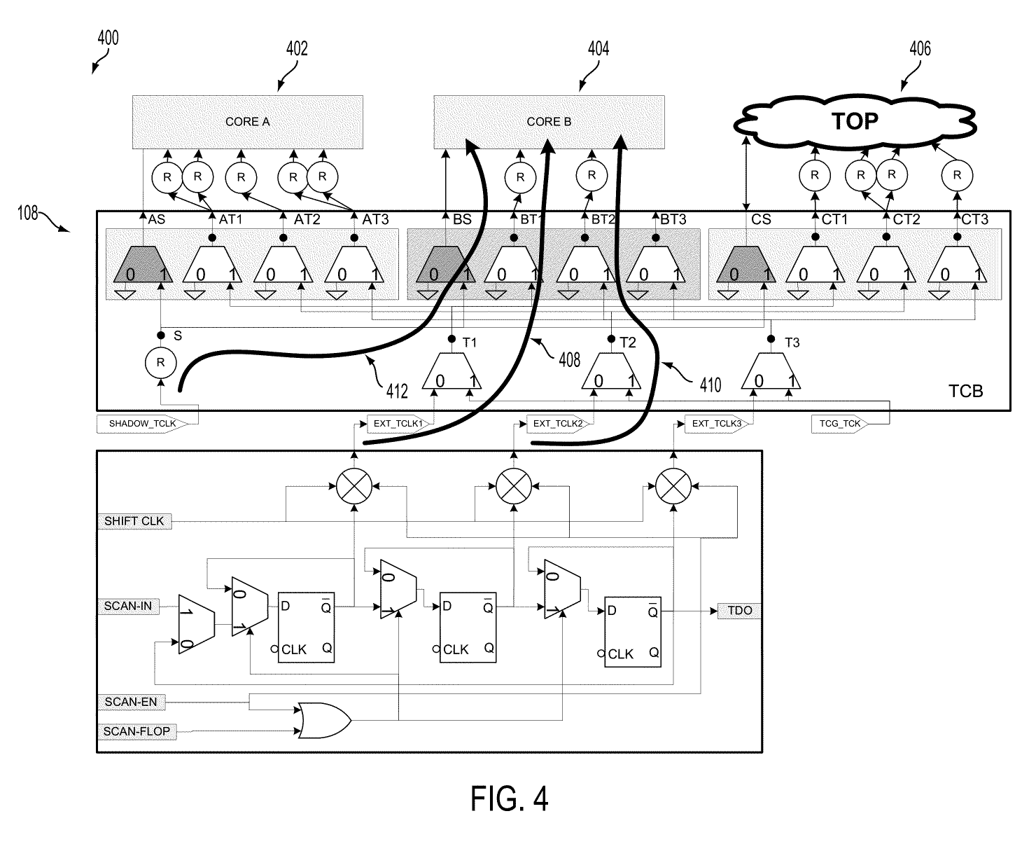

FIG. 4 illustrates how different clock requirements are handled. Core B 404 uses only two clocks 408 and 410. During the ATPG of core B 404, the one-hot decoder function is modified to have only two clocks 408 and 410 rest while the other clock enable signal 412 is constrained to 0. This provides an advantage over traditional OHD logic, as the above configurability is not possible.

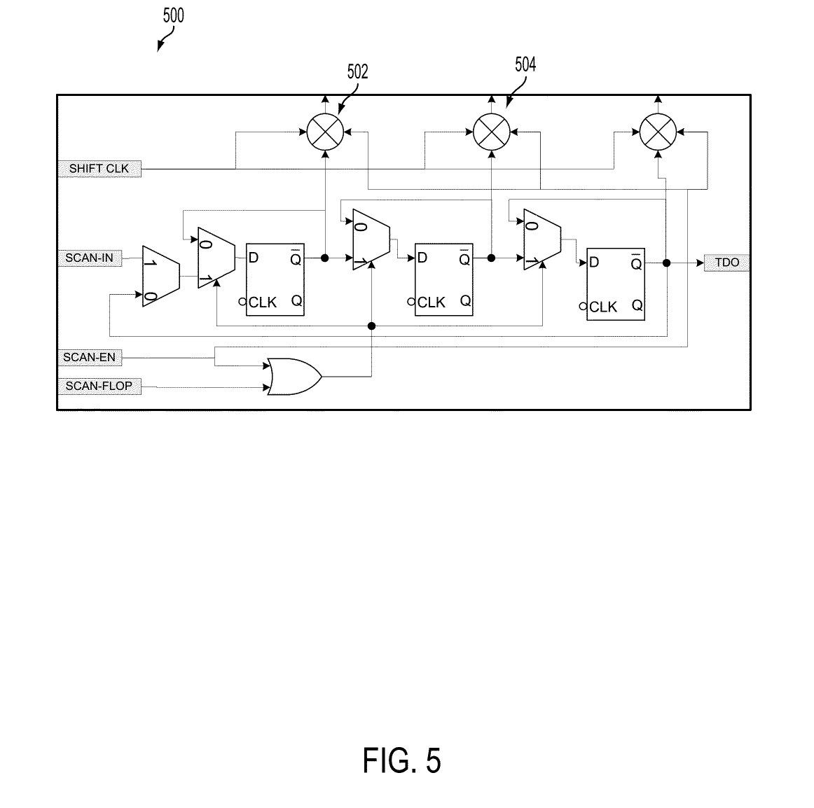

FIG. 5 further illustrates handling different clock requirements. Specifically, FIG. 5 shows that two clock gates 502 and 504, may be enabled together, to provide reductions in test time. This parallel testing is not possible with current OHD methods.

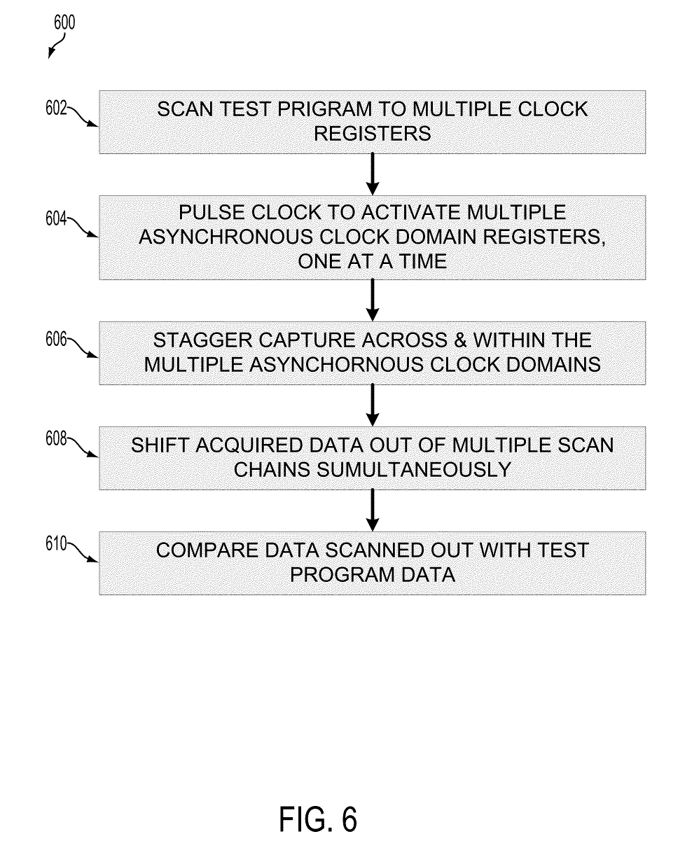

FIG. 6 is a flowchart of a method of capturing clock waveforms. The method 600 begins with scanning a test program to multiple clock registers in step 602. In step 604 the clock is pulsed to activate multiple asynchronous clock domain registers, one at a time. Capture is then staggered across and within the multiple asynchronous clock domains in step 606. Next, in step 608, the acquired data is shifted out of multiple scan chains simultaneously. Then, in step 610, a comparison is made of the data scanned out with the test program data.

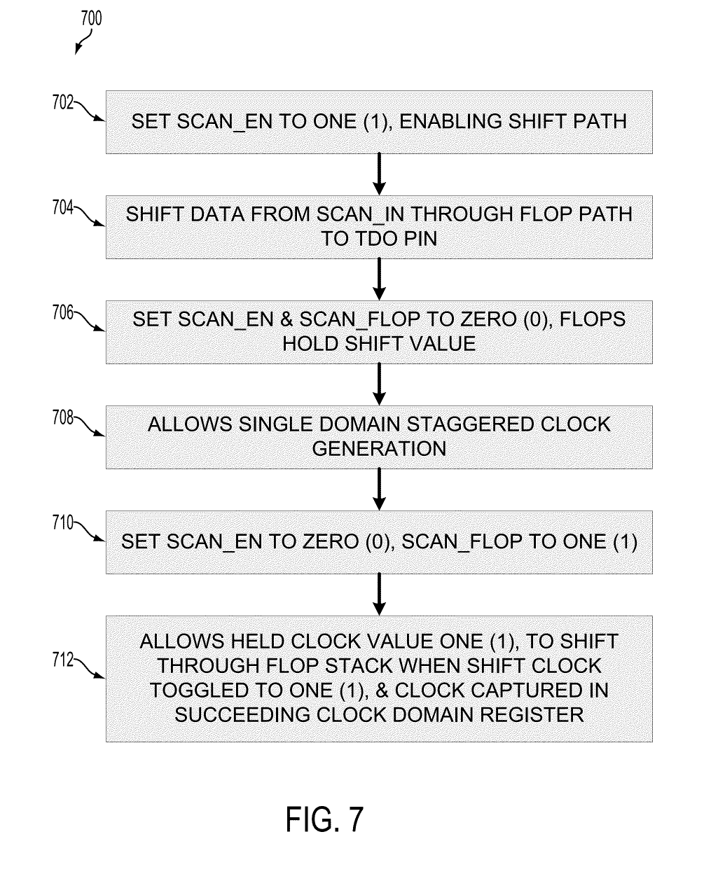

FIG. 7 provides flowcharts of methods 700 for handling different clock requirements. In step 702, a SCAN_EN is set to 1. This enables a shift path, allowing data present at the SCAN_IN pin to shirt through the flop path and be present on the TDO pin in step 704. In further method, in step 706 when SCAN_EN and SCAN-FLOP are set to 0 the flops hold the shifted value. This allows a single domain staggered clock generation when SHIFT-CLK is toggled in step 708. A further method provides in step 710 that when SCAN-EN is set to 0 and SCAN-FLOP is set to 1 in step 710, the held clock value 1 is shifted through the flop stack when SHIFT-CLK is toggled to 1 and the clock is captured in each successive clock domain register in step 712.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media. The processor may be, or may include, a digital signal processor (DSP). The processor may include an amount of special dedicated hardware that performs some selected amount of the processing in hardware rather than in software or firmware.

Although certain specific embodiments are described above for instructional purposes, the teachings of this patent document have general applicability and are not limited to the specific embodiments described above. Accordingly, various modifications, adaptations, and combinations of the various features of the described specific embodiments can be practiced without departing from the scope of the claims that are set forth below.

What is claimed is:

1. A method for testing an electronic chip, comprising:
scanning a test program into multiple clock registers;
pulsing a clock to activate multiple asynchronous clock domain registers one at a time;
staggering capture across and within multiple asynchronous clock domains;
shifting acquired data out of multiple scan chains simultaneously; and
comparing data scanned out with the test program data.

2. The method of claim 1, wherein scanning the test program into multiple clock registers further comprises:
setting a flop to a logic high; and
shifting data from an input pin through a flop to an output pin.

3. The method of claim 1, wherein pulsing a clock to activate multiple asynchronous clock domain registers one at a time further comprises:
setting a first control line to a logic zero;
setting a second control line to a logic zero; and
generating a clock using a staggered single domain.

4. The method of claim 3, wherein the first and second control lines hold a shifted value.

5. The method of claim 1, further comprising:
setting a first control line to a logic zero;
setting a second control line to a logic high; and
shifting a clock value.

6. The method of claim 5, wherein the clock value is a logic high.

7. The method of claim 6, wherein the clock value is shifted through a flop stack when a shift clock is toggled to a logic high.

8. The method of claim 7, wherein the clock is captured in successive clock domain registers.

9. An apparatus for testing an electronic chip, comprising:
a chip core having at least one core embedded;
at least one clock register;
at least two asynchronous clock domains; and
a programmable multiple clock generator.

10. The apparatus of claim 9, further comprising:
a memory for storing a test program.

11. An apparatus for testing an electronic chip, comprising:
means for scanning a test program into multiple clock registers;
means for pulsing a clock to activate multiple asynchronous clock domain registers one at a time;
means for staggering capture across and within the multiple asynchronous clock domains;
means for shifting acquired data out of multiple scan chains simultaneously; and
means for comparing data scanned out with test program data.

12. The apparatus of claim 11, wherein the means for scanning a test program into multiple clock registers further comprises:
means for setting a flop to a logic high; and
means for shifting data from an input pin through a flop to an output pin.

13. The apparatus of claim 11, wherein the means for pulsing a clock to activate multiple asynchronous clock domain registers one at a time further comprises:
means for setting a first control line to a logic zero;
means for setting a second control line to a logic zero; and
means for generating a clock using a staggered single domain.

14. The apparatus of claim 13, wherein the means for setting a first control line and the means for setting a second control line hold a shifted value.

15. The apparatus of claim 11, further comprising:
means for setting a first control line to a logic zero;
means for setting a second control line to a logic high; and
means for shifting a clock value.

16. The apparatus of claim 15, further comprising means for shifting the clock value to a logic high.

17. The apparatus of claim 16, further comprising means for shifting the clock value through a flop stack when a shift clock is toggled by toggling means to a logic high.

18. The apparatus of claim 17, further comprising means for capturing a clock in successive clock domain registers.

19. A non-transitory computer-readable media including program instructions, which when executed by a processor cause the processor to perform a method comprising the steps of:
scanning a test program into multiple clock registers;
pulsing a clock to activate multiple asynchronous clock domain registers one at a time;
staggering capture across and within the multiple asynchronous clock domains;
shifting acquired data out of multiple scan chains simultaneously; and
comparing data scanned out with the test program data.

20. The non-transitory computer-readable media including the program instructions of claim 19, further comprising instructions for:
setting a flop to a logic high; and
shifting data from an input pin through a flop to an output pin.

21. The non-transitory computer-readable media including the program instructions of claim 19, further comprising instructions for:
setting a first control line to a logic zero;
setting a second control line to a logic zero; and
generating a clock using a staggered single domain.

22. The non-transitory computer-readable media including the program instructions of claim 21, wherein the first and second control lines hold a shifted value.

23. The non-transitory computer-readable media including the program instructions of claim 19, further comprising instructions for:
setting a first control line to a logic zero;
setting a second control line to a logic high; and
shifting a clock value.

24. The non-transitory computer-readable media including the program instructions of claim 23, wherein the clock value is a logic high.

25. The non-transitory computer-readable media including the program instructions of claim 24, wherein the clock value is shifted through a flop stack when a shift clock is toggled to a logic high.

26. The non-transitory computer-readable media including the program instructions of claim 25, wherein the clock is captured in successive clock domain registers.
